(19) United States
(12) Patent Application Publication
(10) Pub. No.: US 2026/0130003 A1
(43) Pub. Date: May 7, 2026

(54) INTERDIGITATED FINGERED-TYPE SPATIALLY MODULATED PHOTODETECTOR WITH EXTRA BIASING FOR CARRIER ACCELERATION IN VISIBLE LIGHT COMMUNICATION

(71) Applicant: Hyperlume Inc., Ottawa (CA)

(72) Inventors: Abdolreza Nabavi, Ottawa (CA); Hossein Fariborzi, Auburndale, MA (US); Mohsen Asad, Ottawa (CA); Morteza Nabavi, Ottawa (CA)

(73) Assignee: Hyperlume Inc., Ottawa (CA)

(21) Appl. No.: 19/054,826

(22) Filed: Feb. 15, 2025

Related U.S. Application Data
(63) Continuation of application No. PCT/CA2024/051453, filed on Nov. 1, 2024.

(51) Int. Cl. H10F 77/14; H10F 39/00; H10F 39/18; H10F 77/122

(52) U.S. Cl. CPC H10F 77/148; H10F 39/014; H10F 39/18; H10F 39/806; H10F 77/122

(57) ABSTRACT

A semiconductor device comprising: a silicon substrate; at least one P+/N-well structure formed on the substrate, the at least one P+/N-well structure comprising a first set of N-well layers coupled to an extra positive extrinsic electric field, and a second set of N-well layers coupled to an extra negative extrinsic electric field; and whereby the extra positive extrinsic electric field and the extra negative extrinsic electric field accelerate movement of carriers in the layers.

### FIELD

Aspects of the disclosure relate to methods and systems for visible light communication systems.

### BACKGROUND

Visible light communication (VLC) is a new paradigm that promises to revolutionize communication links. Incorporating highly parallel optical data links into board-to-board and rack-to-rack interconnects enables these systems with superior performance in terms of density, power dissipation, and cost.

The use of a silicon photodetector integrated with silicon-based CMOS technology is highly appealing for visible light communication (VLC) receivers operating at wavelengths below 850 nm. This integration takes advantage of the cost-effectiveness, reliability, and scalability of silicon technology. By employing PIN photodetector structures, it becomes possible to create dense, parallel, and monolithic optical receivers. However, silicon's poor absorption at VLC wavelengths poses a challenge in designing a highly efficient silicon photodetector within silicon CMOS processes.

High data rate short link communications rely heavily on the speed and responsivity of the photodetector, particularly in chip-to-chip communications. To achieve enhanced responsivity, one approach is using silicon dioxide layer a few microns beneath the substrate surface. By fine-tuning the thickness of the oxide layer, it is possible to optimize the reflectivity at the desired wavelength. Despite this, it should be acknowledged that silicon-on-insulator (SOI) substrates are considerably pricier than bulk silicon substrates.

### SUMMARY

In one of its aspects, a semiconductor device comprising:
a silicon substrate;
at least one P+/N-well structure formed on the substrate, the at least one P+/N-well structure comprising a first set of N-well layers coupled to an extra positive extrinsic electric field, and a second set of N-well layers coupled to an extra negative extrinsic electric field; and
whereby the extra positive extrinsic electric field and the extra negative extrinsic electric field accelerate movement of carriers in the layers.

In another aspect, a method of manufacture of a semiconductor device, the method comprising the steps of:
on a silicon substrate, forming at least one P+/N-well structure comprising a first set of N-well layers and a second set of N-well layers;
coupling the first set of N-well layers to an extra positive extrinsic electric field;
coupling the second set of N-well layers to an extra negative extrinsic electric field; and
whereby the extra positive extrinsic electric field and the extra negative extrinsic electric field accelerate movement of carriers in the layers, thereby improving bandwidth.

In another aspect, there is provided a complementary metal-oxide-semiconductor (CMOS) device, such as a photodetector comprising a spatially modulated (or fingered type) P+/N-well structure with biasing for carrier acceleration. This biasing provides an extrinsic electric field which improves the bandwidth. The arrangement of this photodetector allows for the seamless integration of photodetectors with the other components of a transceiver or receiver circuit, which may include a transimpedance amplifier and the subsequent circuitry.

To address silicon's poor absorption at VLC wavelengths in designing highly efficient silicon photodetector within silicon CMOS processes, as described above, the methods presented herein comprise steps for developing silicon-based photodetectors with wide-bandwidth, enhanced efficiency, and responsivity, while adhering to the design rules of fine nanometer CMOS technology. The device described herein employs a spatially modulated light detector structure of P+/N-well photodetector with a technique of N-well biasing for carrier acceleration, which speeds up the data rate for visible light communication. Some of P+/N-well components in the entire photodetector are shielded with metal layers.

A visible light photodetector (PD) device is fabricated in a standard semiconductor silicon substrate, being formed as a fingered P+/N-well junctions or spatially distributed structure. To implement the device, some components of the PD may be shielded e.g., by a metal layer, while the remainder of the components may be unshielded. The overall device may be used in differential mode amplifications, coping with the effects of slow carriers. In one example, a portion of the N-well layers are grouped and connected to an extra positive bias and the rest are connected to extra negative bias, resulting in an extrinsic electric field which may accelerates the carriers and improve the bandwidth. The metal layers may be stacked on top of each other comprising an entire metal layer or a portion of the metal layer to form gratings to direct the light horizontally and as a means for photon trapping. The metal stack may be used for the entire photodetector or along with local stack of metal layers for local photodetector components.

### BRIEF DESCRIPTION OF THE DRAWINGS

Several exemplary embodiments of the present disclosure will now be described, by way of example only, with reference to the appended drawings in which:

FIG. 1a shows a semiconductor device, such as a photodetector, with spatially distributed components row or columns of components;

FIG. 1b shows a semiconductor device, such as a photodetector, with spatially distributed components row or columns of components, without a shallow trench insulator;

FIG. 2 shows a semiconductor device, such as a photodetector, with spatially distributed components row or columns of components, in one example;

FIG. 3 shows a cross-section of a semiconductor device, such as a photodetector, with spatially distributed components row or columns of components, with different extra bias connection of +V₁ and −V₁ of N-well layers to accelerate the carrier speed;

FIG. 4 shows a cross-section of a metal layer stack on a perimeter of the semiconductor device or a local component as a grating;

FIG. 5a shows a top view of 16 elements of photodetector components, in one example;

FIG. 5b shows a top view of 16 elements of photodetector components with metal strip for shielding one or more components, in one example; and

FIG. 6 shows a top view of 16 elements of photodetector components with metal layers stacked as gratings to direct the light horizontally and as a means for photon trapping, in one example.

### DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of the invention and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

Referring now to the Figures, the structures of photodiodes may be formed, and may be arranged in a finger-type or a spatially modulated configuration, to provide efficient device operation in visible light for data communications. Moreover, these structures can also advantageously provide photon trapping as well as carrier acceleration, by using properly designed stacked metal layers and/or dummy transistors (MOSFETs/FINFETs) in the perimeter of the entire photodiode or the perimeter of the local components of photodiode within the entire photodiode. In one example, the gate of the transistors may be used instead of a shadow trench insulator (STI), and the STI may prevent or minimize the premature edge breakdown in a N+/P-substrate. Also, it is possible to use each drain and source of transistors as photodetector components and the P+-ring /N+-ring as shielded photodetector components. Also, the drain and source of transistor device may be shorted.

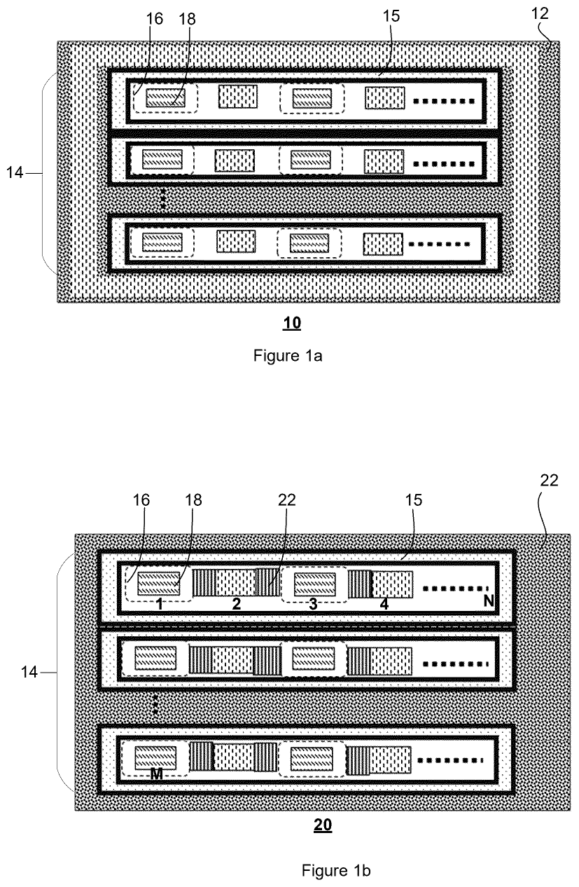

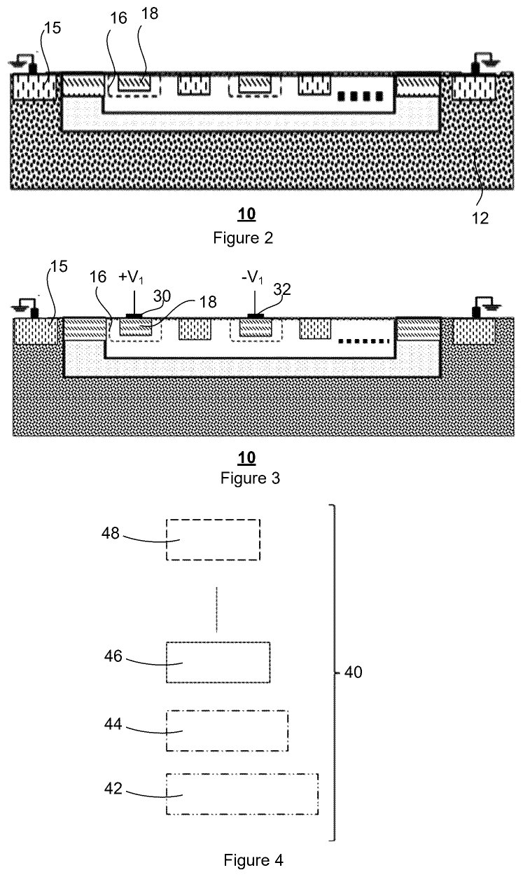

Referring now to FIG. 1a, FIG. 1b, FIG. 2, and FIG. 3, the structures of photodiode may be implemented in interdigitated finger P+/NW/P-sub configuration or meshed spatially modulated arrangement, with some components shielded with metal layers to provide efficient device operation in visible light for data communications. The shielded components are connected as an electrode and the unshielded ones as the other electrode, providing a pair of differential photodetectors. Moreover, these structures can also advantageously provide carrier acceleration with an extrinsic electric field which improves the bandwidth, by using properly designed biasing of the N-well layers.

The SML PDs are connected to a differential transimpedance amplifier (TIA) to perform the subtraction. The differential TIA offers several advantages, including higher rejection of supply noise and better linearity by suppressing even harmonics compared to a single-ended TIA.

In more detail, FIG. 1a shows a photodetector 10 on a single P-substrate 12, in one example. The photodetector 10 comprises an array 14 of P+, N+/N-well layers within Deep N-well layer on the P-substrate 12 with a P+ ring 15, which may be connected to ground. In one example, the single P-substrate 12 comprises an array 14 with N+ well layers 16 and P+ layers 18, spatially distributed in the P-substrate 12. M is the number of N+/N-well layer 16 components and P+ layer 18 components in Y-direction, whereas the number of these components 16, 18 in the X-direction may be N.

FIG. 1b shows a photodetector 20 on a single P-substrate 12, in one example. The photodetector 20 comprises an array 14 of P+, N+/N-well layers within Deep N-well layer on the P-substrate 12 with a P+ ring 15, which may be connected to ground. In one example, the single P-substrate 12 comprises an array 14 with N-well layers 16 and P⁺layers 18, spatially distributed in the P-substrate 12. A shallow trench insulator (STI) 22 may be used between N-well layers 16 and P+ well layers 18 to minimize premature edge breakdown in a N+/P-substrate 12 within the semiconductor device 20 structure. M is the number of N+/N-well layer 16 components and P+ layer 18 components in Y-direction, whereas the number of these components in the X-direction may be N.

FIG. 2 shows a cross-section of spatially distributed components (or one row fingered type style) of a photodetector 10 on substrate 12. The photodetector 30 comprises P+, N+/N-well layers 16, 18, respectively, within a deep N-well layer on the P-substrate 12 with a P+ ring 15 which may be connected to ground.

FIG. 3 shows a cross-section of spatially distributed components of photodetectors (or one row fingered type style) of a photodetector 10 with extra bias connections 30, 32 of +V1 and −V1 to N-well to accelerate the carrier speed.

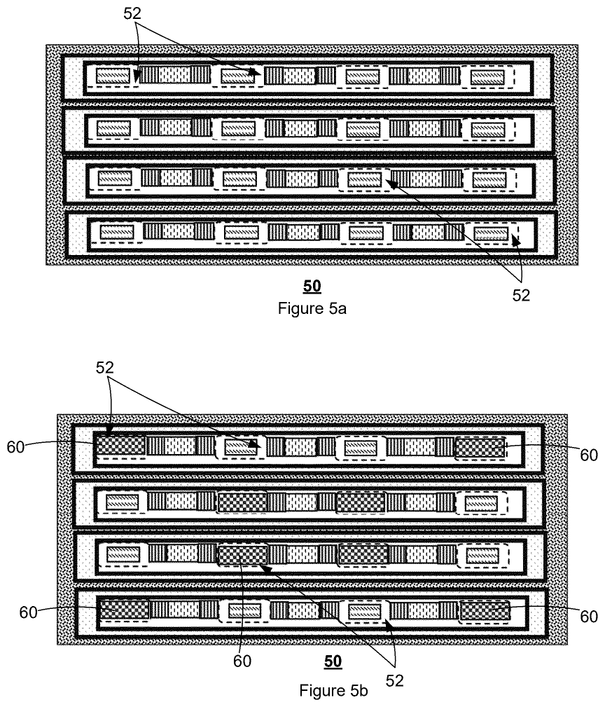

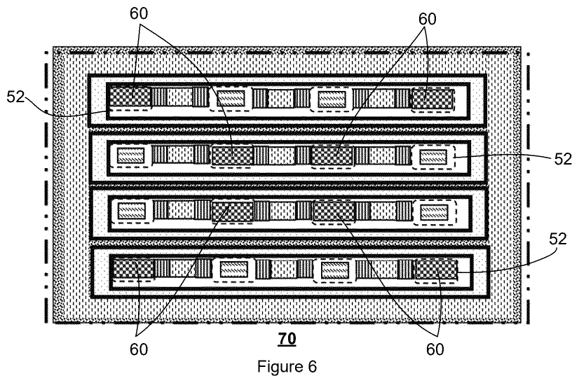

Referring to FIG. 4, FIG. 5a, FIG. 5b, and FIG. 6, metal layers 42-48 (stacked from metal one to the last metal) may be used as gratings to direct the light horizontally and as a means for photon trapping. The metal stack 40 may be used for the entire photodetector 10, 50, or 70 and/or along with local stack of metal layers 42-48 for local photodetector components.

By utilizing the NW cathode as an output and connecting the P+anode to a negative bias volt-age, the desired functionality can be achieved. Alternatively, connecting the P+ anode to the amplifier input and biasing the NW cathode with a positive voltage is also a viable option. Nonetheless, the latter method is often preferred due to its ability to mitigate the impact of slow diffusion currents originating from the substrate. The N+ fingers may be interconnected by a metal layer outside the photo-sensitive area. The delayed current resulting from slow diffusion is deducted from the instantaneous current, which includes both slow diffusion and fast drift components, in order to calculate the “effective detector” current. This effective detector current exhibits a quicker response time due to the elimination of some slow diffusive carriers through the sub-traction process.

The photodetector 10, 50, or 70 is formed from the P+/NW junction, and the P+ contacts (guard ring) for the substrate may be tied to ground to reduce the PD capacitance and to block the substrate diffusion current. The P+/NW junction is employed to detect the optical signal, while the P-sub/N-well junction acts as a guard to collect the slowly diffusing carriers that are produced in the substrate.

In more detail, FIG. 4 shows a cross-section of a metal layer stack 40 used around the entire semiconductor device 10, such as a photodetector, or a local component as a grating to direct the light horizontally and as a means for photon trapping, using one or more layers. In one example, the metal layer stack 40 comprises metal layers available in a standard CMOS technology, such as a first metal layer 42, a second metal layer 44, a third metal layer 46, and a fourth metal layer 48. The metal layer stack 40 may comprise metals layers 42-48 of the same type of metal or different types of metal.

FIG. 5a shows a top view of spatially distributed components (or one row Fingered type style) of a photodetector 50 on substrate 12. The photodetector 50 comprises 16 elements of photodetector components 50.

FIG. 5b shows a top view of spatially distributed components (or one row fingered type style) of a photodetector 50 on a substrate 12 with a metal strip 60. The photodetector 50 can be enhanced by the spatially modulated structure through the subtraction of a portion of the diffusion current. Floating metal strips 60 shield some of the components of the photodetector 50 from the incident light, forming the “deferred detector”. The remaining unshielded components are connected to create the “immediate detector”.

When the photodetector 50 is exposed to light, the metal mask 60 prevents the light from reaching the deferred detector, causing it to be absorbed by the immediate detector. Photocarriers are produced beneath the immediate detector area rather than under the deferred area. The incident light is modulated spatially based on the areas covered and uncovered by the metal strip 60. Carriers generated near an illuminated junction are more likely to be captured by the immediate detector junctions. Carriers generated in bulk (through diffusion) have an equal chance of reaching either the immediate or deferred detector junctions. The slow diffusion of the deferred current is removed from the immediate current (which includes both slow diffusion and fast drift components) to determine the “effective detector” current. The effective detector current exhibits a quicker response because the subtraction minimizes or eliminates some of the slow diffusive carriers.

The spatial modulated light (SML) photodiode speed (bandwidth) is determined by the diffusion current in the p-substrate, and while the speed is enhanced, the responsivity de-creases. Increasing the number of photodetector components leads to more deferred detector current being subtracted from the immediate detector current, as a portion of the light is reflected from the shielded components. The spatially modulated detector, slit into two photodetectors, as a smaller capacitance compared to a reference photodetector without spatially modulated configuration. The receiver sensitivity increases slightly due to the lower capacitance of the spatially modulated configuration. The lower responsivity of the spatially modulated detector is somewhat offset by the device's lower capacitance.

FIG. 6 shows a top view of spatially distributed components (or one row Fingered type style) of a photodetector 70 on substrate 12. The photodetector 70 comprises a shallow trench insulator (STI) 22 between N-well layers 16 and P+ well layers 18 to minimize premature edge breakdown in a N+/P-substrate 12 within the semiconductor device 70 structure. The photodetector 70 further comprises a metal strip 60 for preventing light illumination on all of the components 52, as described above. This may be used locally for some part of the components.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Accordingly, the above description of example implementations does not define or constrain this disclosure. Other changes, substitutions, and alterations are also possible without departing from the spirit and scope of this disclosure.

### REFERENCES

[1] Horst Zimmermann, Silicon Optoelectronic Integrated Circuits, Second Edition, 2018.
[2] Myung-Jae Lee, et al, Bandwidth Improvement of CMOS-APD With Carrier-Acceleration Technique, IEEE Photonics Technology Letters, Vol. 27, No. 13, 2015.
[3] Toshiyuki Shimotori, et al, “Characterization of APDs fabricated by 0.18 μm CMOS process in blue wavelength region”, Opto-Electronics and Communications Conference (OECC 2012) Technical Digest July 2012.
[4] Jia Cong et al, Integrated Color Photodetectors in 40-nm Standard CMOS Technology, IEEE Photonics Technology Letters, Vol. 31, No. 24, 2019.

1. A semiconductor device comprising:
a silicon substrate;
at least one P+/N-well structure formed on the substrate, the at least one P+/N-well structure comprising a first set of N-well layers coupled to an extra positive extrinsic electric field, and a second set of N-well layers coupled to an extra negative extrinsic electric field; and
whereby the extra positive extrinsic electric field and the extra negative extrinsic electric field accelerate movement of carriers in the layers.

2. The semiconductor device of claim 1, wherein the at least one P+/N-well structure comprises alternating N-well layers of the first set of N-well layers and N-well layers of the second set of N-well layers.

3. The semiconductor device of claim 2, wherein a portion of the N-well layers is shielded by a metal strip.

4. The semiconductor device of claim 3, wherein a portion of the N-well layers is unshielded.

5. The semiconductor device of claim 4, wherein the portion of the shielded N-well layers and a portion of the unshielded N-well layers are used as a differential photodetector pair to supply the input signal for a transimpedance amplifier (TIA) circuit, thereby minimizing the effect of slow carriers and improving speed of the carriers, and increases data rates for visible light communication.

6. The semiconductor device of claim 4, wherein the shielding metal strip comprises a pattern of N-well layers and/or N+ well layers.

7. The semiconductor device of claim 6, wherein the shielded components are connected as an electrode, and the unshielded components are connected as the other electrode, thereby providing a pair of differential photodetectors.

8. The semiconductor device of claim 7, comprising a shadow trench insulator (STI) to minimize premature edge breakdown in a N+/P-substrate within the semiconductor device structure.

9. The semiconductor device of claim 8, wherein a perimeter of the semiconductor device comprises metal layers.

10. The semiconductor device of claim 8, wherein a portion of the perimeter of the semiconductor device comprises metal layers.

11. The semiconductor device of claim 9, comprising a grating.

12. The semiconductor device of claim 11, wherein the grating is formed of stacked metal layers on at least one component in an array of semiconductor devices, wherein the grating directs light horizontally.

13. The semiconductor device of claim 9, comprising a means for photon trapping.

14. The semiconductor device of claim 13, wherein the means for photon trapping comprises the metal layers on at least one component in an array of semiconductor devices.

15. The semiconductor device of claim 1, wherein the semiconductor device is a silicon-based complementary metal-oxide semiconductor (CMOS) photodetector (PD).

16. The semiconductor device of claim 15, wherein the at least one P+/N-well structure comprises a finger-type structure.

17. The semiconductor device of claim 15, wherein the at least one P+/N-well structure comprises a meshed spatially modulated light detector structure.

18. A method of manufacture of a semiconductor device, the method comprising the steps of:
on a silicon substrate, forming at least one P+/N-well structure comprising a first set of N-well layers and a second set of N-well layers;
coupling the first set of N-well layers to an extra positive extrinsic electric field;
coupling the second set of N-well layers to an extra negative extrinsic electric field; and
whereby the extra positive extrinsic electric field and the extra negative extrinsic electric field accelerate movement of carriers in the layers, thereby improving bandwidth.

19. The method of claim 18, comprising a step of configuring the at least one P+/N-well structure as a finger-type structure.

20. The method of claim 18, comprising a step of configuring the at least one P+/N-well structure as a meshed spatially modulated light detector structure.

21. The method of claim 18, wherein the device is a silicon-based complementary metal-oxide semiconductor (CMOS) photodetector (PD).
